(19) United States
(12) Patent Application Publication
(10) Pub. No.: US 2025/0142780 A1
(43) Pub. Date: May 1, 2025

(54) HEAT SINK

(71) Applicants: COOLER MASTER CO., LTD., Taipei City (TW); NATIONAL YANG MING CHIAO TUNG UNIVERSITY, Hsinchu City (TW)

(72) Inventors: Hao-Jun CHEN, Hsinchu City (TW); Chi-Chuan WANG, Taipei City (TW)

(73) Assignees: COOLER MASTER CO., LTD., Taipei City (TW); NATIONAL YANG MING CHIAO TUNG UNIVERSITY, Hsinchu City (TW)

(21) Appl. No.: 18/792,330

(22) Filed: Aug. 1, 2024

(30) Foreign Application Priority Data
Oct. 30, 2023 (TW) 112141530

(51) Int. Cl. H05K 7/20

(52) U.S. Cl. CPC H05K 7/2039

(57) ABSTRACT

A heat sink includes a thermally conductive base. The thermally conductive base has a first surface, a second surface, a guiding surface and an accommodating recess. The second surface faces away from the first surface. The guiding surface are connected to the first surface and the second surface. The guiding surface is not perpendicular to the first surface and the second surface. The accommodating recess is located at the first surface. The thermally conductive base has an inner bottom surface and an inner annular side surface which surround and form the accommodating recess. The inner annular side surface is connected to the inner bottom surface. The accommodating recess accommodates a heat source. The inner bottom surface is thermally coupled to the heat source.

### CROSS-REFERENCE TO RELATED APPLICATIONS

This non-provisional application claims priority under 35 U.S.C. § 119 (a) on Patent Application No(s). 112141530 filed in ROC, on Oct. 30, 2023, the entire contents of which are hereby incorporated by reference.

### TECHNICAL FIELD

The present disclosure relates to a heat sink, more particularly to a heat sink having a guiding surface.

### BACKGROUND

With rapid development of technology, computation performances of various electronic components have also improved significantly, while a large amount of heat has been generated at the same time. The electronic components may be damaged easily during operating due to high temperature, thereby affecting the reliability thereof. Thus, heat dissipation devices are generally provided to dissipate heat generated by the electronic components, so that the electronic components can operate within an adequate temperature range.

For example, the electronic components can be cooled by a spray cooling system to maintain the performance and lifespan thereof. The so-called “spray cooling system” is to spray coolant on a heat source via high pressure nozzles so as to cool the heat source. At this moment, the coolant may flow vertically along a cooling device of the spray cooling system to form a falling film cooling. However, the cooling device of conventional spray cooling system is attached to one side of the heat source merely, which is insufficient to dissipate heat generated by the heat source, thereby causing the heat source to overheat. In addition, when the coolant from the conventional spray cooling system flows vertically and hits the cooling device, the coolant may splash outward, such that the coolant is unable to sufficiently perform heat exchange with the cooling device, thereby reducing the cooling efficiency. Therefore, how to improve the heat dissipation efficiency of heat sink is one of the problems required to be addressed.

### SUMMARY

The present disclosure provides a heat sink with desired heat dissipation efficiency.

One embodiment of the present disclosure provides a heat sink including a thermally conductive base. The thermally conductive base has a first surface, a second surface, a guiding surface and an accommodating recess. The second surface faces away from the first surface. Two opposite sides of the guiding surface are connected to the first surface and the second surface, respectively. The guiding surface is not perpendicular to the first surface and the second surface. The accommodating recess is located at the first surface. The thermally conductive base has an inner bottom surface and an inner annular side surface which surround and form the accommodating recess. The inner annular side surface is connected to a periphery of the inner bottom surface. The accommodating recess is configured to accommodate the heat source. The inner bottom surface is configured to be thermally coupled to the heat source.

According to the heat sink as described in the above embodiments, the thermally conductive base of the heat sink covers the heat source, and the heat sink has the guiding surface, such that the guiding surface can guide the coolant flowing as the wall surface flow to pass by the second surface of the heat sink to dissipate heat generated by the heat source effectively. In addition, the guiding surface can reduce a possibility that the coolant splashes outward due to hitting the heat sink, such that the coolant can sufficiently perform heat exchange with the heat sink. Accordingly, the heat dissipation efficiency of the heat sink can be improved.

### BRIEF DESCRIPTION OF THE DRAWINGS

The present disclosure will become more fully understood from the detailed description given hereinbelow and the accompanying drawings which are given by way of illustration only and thus are not limitative of the present disclosure and wherein:

FIG. 1 is a perspective view of a heat sink in accordance with an embodiment of the present disclosure;

FIG. 2 is another perspective view of the heat sink in FIG. 1;

FIG. 3 is a cross-sectional view of the heat sink in FIG. 1;

FIG. 4 is another cross-sectional view of the heat sink in FIG. 1; and

FIG. 5 is a cross-sectional view showing that a coolant passes by the heat sink in FIG. 1.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

In addition, the terms used in the present disclosure, such as technical and scientific terms, have its own meanings and can be comprehended by those skilled in the art, unless the terms are additionally defined in the present disclosure. That is, the terms used in the following paragraphs should be read on the meaning commonly used in the related fields and will not be overly explained, unless the terms have a specific meaning in the present disclosure.

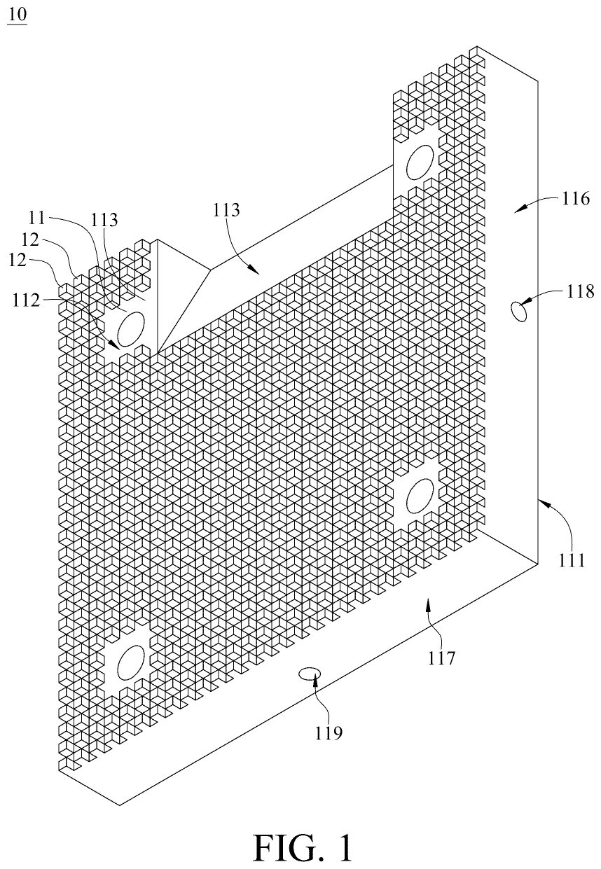

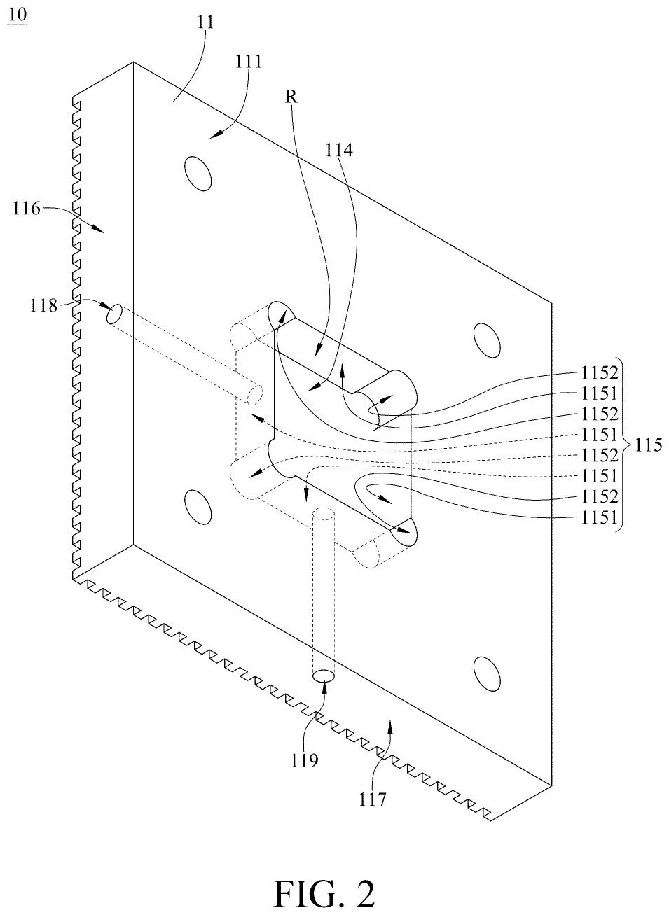

Please refer to FIG. 1 and FIG. 2, where FIG. 1 is a perspective view of a heat sink 10 in accordance with an embodiment of the present disclosure, and FIG. 2 is another perspective view of the heat sink 10 in FIG. 1.

In this embodiment, a heat sink 10 is, for example, an upright heat sink. The heat sink 10 is disposed on, for example, an upright circuit board in a server (not shown), and is configured to be thermally coupled to a heat source (not shown) disposed on the circuit board. The heat source is, for example, a chip. Two objects are thermally coupled to each other, which refers that these two objects are in directly thermal contact to each other, or these two objects are connected to each other via other thermally conductive media therebetween. The heat sink 10 includes a thermally conductive base 11 and a plurality of heat dissipation structures 12. The thermally conductive base 11 has a first surface 111, a second surface 112, a guiding surface 113 and an accommodating recess R.

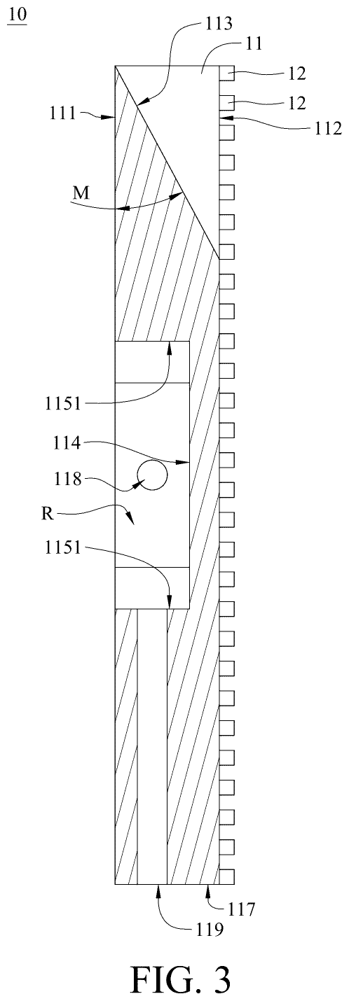

Please refer to FIG. 1 to FIG. 3, where FIG. 3 is a cross-sectional view of the heat sink 10 in FIG. 1. The second surface 112 faces away from the first surface 111 and the heat source. The guiding surface 113 is, for example, a flat surface, and is configured to guide a coolant (not shown) to flow thereon. The coolant is, for example, a fluorinated liquid. Two opposite sides of the guiding surface 113 are connected to the first surface 111 and the second surface 112, respectively. An angle M between the guiding surface 113 and the first surface 111 is, for example, an acute angle, and the angle M is, for example, greater than 0 degrees, and is smaller than or equal to 45 degrees. For example, the angle M between the guiding surface 113 and the first surface 111 is 28.3 degrees. In addition, the guiding surface 113 is not perpendicular to the second surface 112. Accordingly, the guiding surface 113 can guide the coolant to flow to the second surface 112.

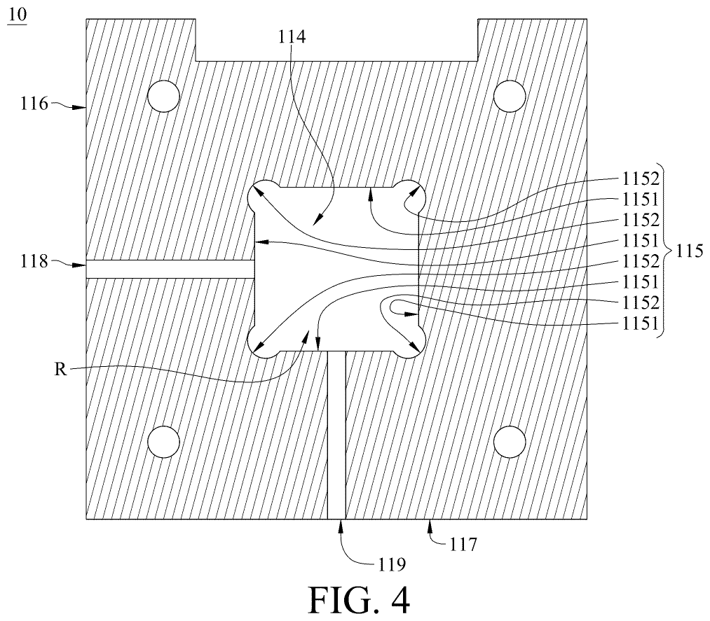

Please refer to FIG. 1 to FIG. 4, where FIG. 4 is another cross-sectional view of the heat sink 10 in FIG. 1. The accommodating recess R is located at the first surface 111 of the thermally conductive base 11. In detail, the thermally conductive base 11 has an inner bottom surface 114 and an inner annular side surface 115 which surround and form the accommodating recess R. The inner annular side surface 115 is connected to a periphery of the inner bottom surface 114. The inner annular side surface 115 has a plurality of flat portions 1151 and a plurality of curved portions 1152. The curved portions 1152 are located at corners of the accommodating recess R, respectively. The flat portions 1151 are connected to the curved portions 1152, respectively, such that the flat portions 1151 and the curved portions 1152 together surround the accommodating recess R.

The accommodating recess R is configured to accommodate the heat source, such that the thermally conductive base 11 covers the heat source. In addition, the inner bottom surface 114 is configured to be thermally coupled to the heat source. The heat dissipation structures 12 are, for example, thermally conductive protrusions, such as rectangular pillars. The heat dissipation structures 12 protrude from the second surface 112 of the thermally conductive base 11, so that heat generated by the heat source can be transferred to the coolant.

In this embodiment, the coolant flows by the upright heat sink 10 along a wall surface of the circuit board so as to form a wall surface flow. Compared with a conventional upright heat sink, the heat sink does not cover the heat source, such that the wall surface flow does not pass by the second surface of the heat sink. Thus, the heat dissipation efficiency may be reduced. In addition, the heat sink does not have the inclined guiding surface. Thus, when the coolant flows to the heat sink along the wall surface of the circuit board, the coolant may hit the heat sink and splash outward, so that it may cause a waste of the coolant, thereby further reducing the heat dissipation efficiency. In this embodiment, the thermally conductive base 11 of the heat sink 10 covers the heat source, and the heat sink 10 has the guiding surface 113, such that the guiding surface 113 can guide the coolant flowing as the wall surface flow to pass by the second surface 112 of the heat sink 10. In addition, the guiding surface 113 can reduce a possibility that the coolant splashes outward due to hitting the heat sink 10, such that the coolant can sufficiently perform heat exchange with the heat sink 10. Accordingly, the heat dissipation efficiency of the heat sink 10 can be improved.

In this embodiment, the thermally conductive base 11 further has a first side surface 116, a first through hole 118, a second side surface 117 and a second through hole 119. Two opposite sides of the first side surface 116 are connected to the first surface 111 and the second surface 112, respectively. The first side surface 116 and the guiding surface 113 are located at, for example, two adjacent sides of the thermally conductive base 11, respectively. The first through hole 118 is connected to the first side surface 116 and the inner annular side surface 115.

Two opposite sides of the second side surface 117 are connected to the first surface 111 and the second surface 112, respectively. The first side surface 116 and the second side surface 117 are located at different sides of the thermally conductive base 11, respectively. The second side surface 117 and the guiding surface 113, for example, are located at two opposite sides of the thermally conductive base 11, respectively. The second through hole 119 is connected to the second side surface 117 and the inner annular side surface 115.

In this embodiment, the guiding surface 113 is a flat surface, but the present disclosure is not limited thereto. In other embodiments, the guiding surface may be a curved surface.

In this embodiment, the heat dissipation structures 12 are rectangular pillars, but the present disclosure is not limited thereto. In other embodiments, the heat dissipation structures may be cylindrical pillars.

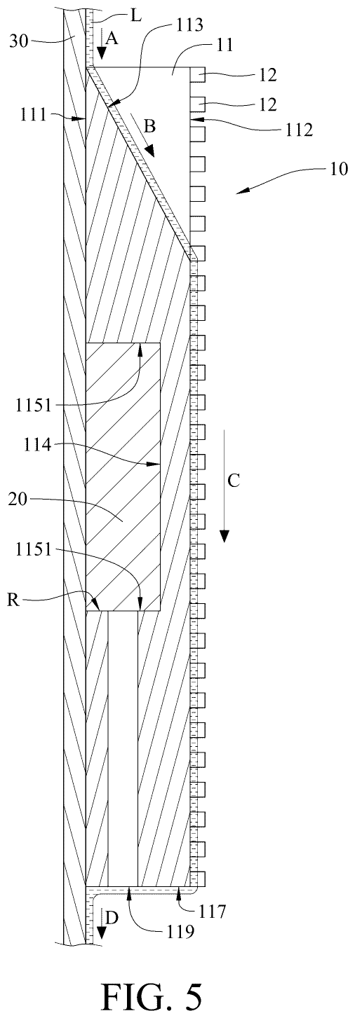

Please refer to FIG. 5, where FIG. 5 is a cross-sectional view showing that a coolant L passes by the heat sink 10 in FIG. 1. In this embodiment, the heat sink 10 is disposed on the upright circuit board 30. Firstly, the coolant L flows on the wall surface of the circuit board 30 to form the wall surface flow, and flows toward the guiding surface 113 of the thermally conductive base 11 of the heat sink 10 along a direction A. Then, the coolant L flows on the guiding surface 113, and flows toward the second surface 112 of the thermally conductive base 11 of the heat sink 10 along a direction B via the guidance of the guiding surface 113. Then, the coolant L flows on the second surface 112 along a direction C. At this moment, the heat generated by the heat source 20 disposed on the circuit board 30 and located in the accommodating recess R is transferred to the coolant L via the second surface 112 and the heat dissipation structures 12. Then, the coolant L absorbing the heat flows along a direction D and leaves the heat sink 10.

According to the heat sink as described in the above embodiments, the thermally conductive base of the heat sink covers the heat source, and the heat sink has the guiding surface, such that the guiding surface can guide the coolant flowing as the wall surface flow to pass by the second surface of the heat sink to dissipate heat generated by the heat source effectively. In addition, the guiding surface can reduce a possibility that the coolant splashes outward due to hitting the heat sink, such that the coolant can sufficiently perform heat exchange with the heat sink. Accordingly, the heat dissipation efficiency of the heat sink can be improved.

It will be apparent to those skilled in the art that various modifications and variations can be made to the present disclosure. It is intended that the specification and examples be considered as exemplary embodiments only, with a scope of the present disclosure being indicated by the following claims.

What is claimed is:

1. A heat sink, configured to be thermally coupled to a heat source, the heat sink comprising:
a thermally conductive base, having a first surface, a second surface, a guiding surface and an accommodating recess, wherein the second surface faces away from the first surface, two opposite sides of the guiding surface are connected to the first surface and the second surface, respectively, the guiding surface is not perpendicular to the first surface and the second surface, the accommodating recess is located at the first surface, the thermally conductive base has an inner bottom surface and an inner annular side surface which surround and form the accommodating recess, the inner annular side surface is connected to a periphery of the inner bottom surface, the accommodating recess is configured to accommodate the heat source, and the inner bottom surface is configured to be thermally coupled to the heat source.

2. The heat sink according to claim 1, further comprising a plurality of heat dissipation structures, wherein the plurality of heat dissipation structures protrude from the second surface of the thermally conductive base.

3. The heat sink according to claim 2, wherein the plurality of heat dissipation structures are rectangular pillars.

4. The heat sink according to claim 1, wherein the guiding surface is a flat surface, and an angle between the guiding surface and the first surface is an acute angle.

5. The heat sink according to claim 4, wherein the angle between the guiding surface and the first surface is greater than 0 degrees, and is smaller than or equal to 45 degrees.

6. The heat sink according to claim 1, wherein the guiding surface is a curved surface.

7. The heat sink according to claim 1, wherein the inner annular side surface has a plurality of flat portions and a plurality of curved portions, the plurality of curved portions are located at corners of the accommodating recess, respectively, the plurality of flat portions are connected to the plurality of curved portions, respectively, and the plurality of flat portions and the plurality of curved portions together surround the accommodating recess.

8. The heat sink according to claim 1, wherein the thermally conductive base further has a first side surface and a first through hole, two opposite sides of the first side surface are connected to the first surface and the second surface, respectively, the first side surface and the guiding surface are located on different sides of the thermally conductive base, respectively, and the first through hole is connected to the first side surface and the inner annular side surface.

9. The heat sink according to claim 8, wherein the thermally conductive base further has a second side surface and a second through hole, two opposite sides of the second side surface are connected to the first surface and the second surface, respectively, the first side surface, the second side surface and the guiding surface are located on different sides of the thermally conductive base, respectively, and the second through hole is connected to the second side surface and the inner annular side surface.

10. The heat sink according to claim 9, wherein the first side surface and the guiding surface are located on two adjacent sides of the thermally conductive base, respectively.

11. The heat sink according to claim 9, wherein the second side surface and the guiding surface are located on two opposite sides of the thermally conductive base, respectively.
